(19) United States
(12) Patent Application Publication
(10) Pub. No.: US 2013/0223126 A1
(43) Pub. Date: Aug. 29, 2013

(54) RESISTIVE MEMORY DEVICE AND MEMORY SYSTEM INCLUDING THE SAME

(71) Applicant: SAMSUNG ELECTRONICS CO., LTD., (US)

(72) Inventors: DONGHUN KWAK, HWASEONG-SI (KR); CHEON AN LEE, HWASEONG-SI (KR)

(73) Assignee: SAMSUNG ELECTRONICS CO., LTD., SUWON-SI (KR)

(21) Appl. No.: 13/706,387

(22) Filed: Dec. 6, 2012

(30) Foreign Application Priority Data
Feb. 27, 2012 (KR) 10-2012-0019802

(51) Int. Cl. G11C 11/21

(52) U.S. Cl. CPC G11C 11/21
USPC 365/148

(57) ABSTRACT

A resistive memory device includes a memory cell array and control logic. The memory cell array includes multiple memory cells connected to multiple word lines and multiple bit lines. The control logic is configured to provide a bit line voltage to at least one selected bit line of the multiple bit lines and to provide the bit line voltage to unselected word lines of the multiple word lines.

### CROSS-REFERENCE

A claim for priority under 35 U.S.C. §119 is made to Korean Patent Application No. 10-2012-0019802, filed Feb. 27, 2012, in the Korean Intellectual Property Office, the entire contents of which are hereby incorporated by reference.

### BACKGROUND

The inventive concepts relate to a semiconductor memory device, and more particularly, relate to a resistive memory device and a memory system including the resistive memory device.

Semiconductor memory devices may be classified as volatile or nonvolatile. A volatile memory device performs read and write operations at a high speed, but loses stored contents when power is removed. A nonvolatile memory device retains the stored contents even when power is off. The nonvolatile memory device is used to store contents that must be retained regardless of whether the nonvolatile memory device has power.

Demand is increasing for nonvolatile memory devices that are highly integrated and have high storage capacities, such as flash memory devices. Flash memory devices are often included in portable electronic devices. Alternative nonvolatile memory devices have been developed that support random access, are highly integrated and have high storage capacities. These nonvolatile memory devices may include ferroelectric random access memory (FRAM) using a ferroelectric capacitor, magnetic RAM (MRAM) using a tunneling magneto-resistive (TRM) film, phase change RAM (PRAM) using chalcogenide alloys, and resistive RAM (RRAM) using a variable resistance material as a data storing medium, for example.

RRAM, in particular, is expected to include favorable memory characteristics, such as high speed, high capacity, and low power. A variable resistance material film of the RRAM shows a reversible resistance variation according to polarity or magnitude of an applied pulse. For example, colossal magnetro-resistive material layer (CMR), having a perovskite structure or a metal oxide layer, the conductive filament of which is generated or disappears by an electric pulse, may be used as the variable resistance material film. Memory (including the RRAM) using a variable resistance material film is referred to as a resistive memory.

Resistive memory elements may be classified as unipolar elements and bipolar elements, according to polarity of a write pulse. In the case of the unipolar resistive memory element, polarity of a set pulse is identical to that of a reset pulse. In the case of the bipolar resistive memory element, polarity of a set pulse is opposite to that of a reset pulse. Resistive memory elements generally require properties such as high capacity, high integration, and high integrity of data.

### SUMMARY

An illustrative embodiment of the inventive concept provides a resistive memory device that includes a memory cell array and control logic. The memory cell array includes multiple memory cells connected to multiple word lines and multiple bit lines. The control logic is configured to provide a bit line voltage to at least one selected bit line of the multiple bit lines and to provide the bit line voltage to unselected word lines of the multiple word lines.

The control logic may include a selected bit line power source configured to generate the bit line voltage.

The control logic may be configured to perform a read operation or a write operation by memory cell unit. The selected bit line power source may be accordingly configured to provide the bit line voltage to one selected bit line and to the unselected word lines, other than one selected word line.

The control logic may be configured to perform a read operation or a write operation by page unit. The selected bit line power source may be accordingly configured to provide the bit line voltage to multiple selected bit lines and to the unselected word lines, other than one selected word line.

The control logic may be configured to perform an erase operation by a sub-block unit. The selected bit line power source may be accordingly configured to provide the bit line voltage to multiple selected bit lines and to the unselected word lines, other than multiple selected word lines.

The resistive memory device may further include a step voltage generator configured to generate a stepwise increasing bit line voltage using power from the selected bit line power source.

Each memory cell of the memory cell array may have a variable resistance element connected to a word line of the multiple word lines and a bit line of the multiple bit lines.

The memory cell array may include a three-dimensional structure.

Another illustrative embodiment of the inventive concept provides a memory system including a resistive memory device configured to provide a bit line voltage to a selected one of multiple bit lines and to unselected word lines of multiple word lines. The memory system further includes a memory controller configured to control the resistive memory device.

The resistive memory device may include a selected bit line power source configured to generate the bit line voltage to be supplied to the selected bit line and the unselected word lines. The resistive memory device may further include a step voltage generator configured to generate a stepwise increasing bit line voltage using power from the selected bit line power source.

The memory controller may include a selected bit line power source configured to generate the bit line voltage to be supplied to the selected bit line and the unselected word lines. The memory controller may further include a step voltage generator configured to generate a stepwise increasing bit line voltage using power from the selected bit line power source.

Another illustrative embodiment of the inventive concept provides a resistive memory device, including a memory cell array, an address decoder, a data input/output circuit, and control logic. The memory cell array includes multiple memory cells connected to multiple word lines and multiple bit lines. The address decoder is connected to the memory cell array via the word lines, and is configured to select at least one word line corresponding to at least one selected memory cell of the memory cells in response to an input address during an internal operation. The data input/output circuit is connected to the memory cell array via the bit lines, and is configured to select at least one bit line corresponding to the at least one selected memory cell in response to a bit line selection signal from the address decoder during the internal operation. The control logic is configured to control the internal operation in response to a control signal, and to provide a bit line voltage to the at least one selected bit line and to unselected word lines of the multiple word lines other than the at least one selected word line, thereby decreasing a voltage difference between the unselected word lines and the at least one selected bit line.

### BRIEF DESCRIPTION OF THE FIGURES

Illustrative embodiments will be more clearly understood from the following detailed description taken in conjunction with the accompanying drawings.

FIG. 1 is a block diagram schematically illustrating a resistive memory device, according to an embodiment of the inventive concept.

FIGS. 2A to 2D are circuit diagrams schematically illustrating memory cell structures of a resistive memory device in FIG. 1, according to an embodiment of the inventive concept.

FIG. 3 is a diagram schematically illustrating a variable resistance element structure of a resistive memory cell in FIGS. 2A to 2D, according to an embodiment of the inventive concept.

FIG. 4 is a graph illustrating hysteresis curves of a resistive memory cell in FIG. 2A, according to an embodiment of the inventive concept.

FIG. 5 is a diagram illustrating an operating method of a resistive memory device, according to an embodiment of the inventive concept.

FIG. 6 is a diagram illustrating an operating method of a resistive memory device, according to another embodiment of the inventive concept.

FIG. 7 is a diagram illustrating an operating method of a resistive memory device, according to still another embodiment of the inventive concept.

FIG. 8 is a diagram illustrating an operating method of a resistive memory device, according to still another embodiment of the inventive concept.

FIGS. 9 and 10 are block diagrams schematically illustrating applications of a resistive memory device, according to embodiments of the inventive concept.

FIG. 11 is a perspective view schematically illustrating an example of a three-dimensional structure of a memory cell array in FIG. 1, according to an embodiment of the inventive concept.

FIG. 12 is a cross-sectional view of a resistive memory cell formed at one layer in FIG. 11, according to an embodiment of the inventive concept.

FIG. 13 is a cross-sectional view of a memory cell array in FIG. 11, according to an embodiment of the inventive concept.

FIG. 14 is a circuit diagram schematically illustrating a memory cell array in FIG. 11, according to an embodiment of the inventive concept.

FIG. 15 is a block diagram schematically illustrating a computing system including a resistive memory device, according to an embodiment of the inventive concept.

FIG. 16 is a block diagram schematically illustrating a memory system in which flash memory is replaced with storage class memory using resistive memory, according to an embodiment of the inventive concept.

FIG. 17 is a block diagram schematically illustrating a memory system in which synchronous dynamic random access memory (DRAM) is replaced with storage class memory using resistive memory, according to an embodiment of the inventive concept.

FIG. 18 is a block diagram schematically illustrating a memory system in which synchronous DRAM and flash memory are replaced with storage class memory using resistive memory, according to an embodiment of the inventive concept.

### DETAILED DESCRIPTION

Embodiments will be described in detail with reference to the accompanying drawings. The inventive concept, however, may be embodied in various different forms, and should not be construed as being limited only to the illustrated embodiments. Rather, these embodiments are provided as examples so that this disclosure will be thorough and complete, and will fully convey the concept of the inventive concept to those skilled in the art. Accordingly, known processes, elements, and techniques are not described with respect to some of the embodiments of the inventive concept. Unless otherwise noted, like reference numerals denote like elements throughout the attached drawings and written description, and thus descriptions will not be repeated. In the drawings, the sizes and relative sizes of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

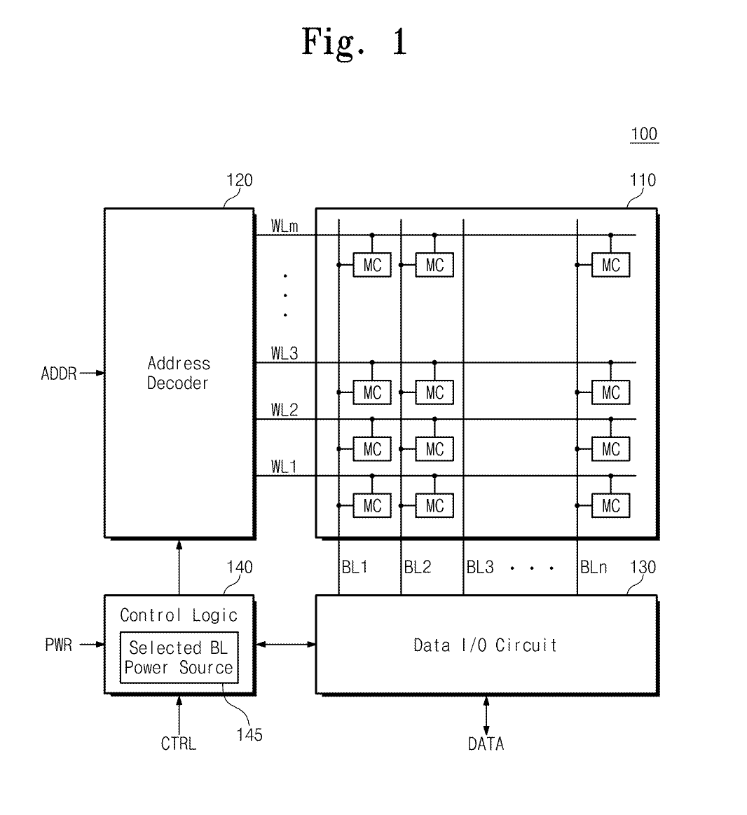

FIG. 1 is a block diagram schematically illustrating a resistive memory device, according to an embodiment. Referring to FIG. 1, a resistive memory device 100 includes a memory cell array 110, an address decoder 120, a data input/output (110) circuit 130, and control logic 140. The resistive memory device 100 according to the depicted embodiment further includes a selected bit line power source 145 configured to supply power to selected bit lines. The selected bit line power source 145 also provides power to unselected word lines. As discussed below, during programming, reading or erasing operations, leakage current is reduced by decreasing the voltage difference between unselected word lines and a selected bit line.

Referring to FIG. 1, the memory cell array 110 includes multiple memory cells MC, each of which stores one or more data bits. The memory cells MC are connected to word lines WL1 to WLm and bit lines BL1 to BLn.

The address decoder 120 is connected to the memory cell array 110 via the word lines WL1 to WLm. The address decoder 120 operates under control of the control logic 140. Generally, the address decoder 120 decodes an input address ADDR to select a word line WL1 to WLm for a particular operation. The address decoder 120 may receive power (e.g., a voltage or a current) from the control logic 140 and provide the received power to selected or unselected word lines.

The term “selected word line” or “selected word lines” indicates a word line or word lines connected to a cell transistor of a memory cell MC to be programmed, erased, or read from among the word lines WL1 to WLm. The term “unselected word line” or “unselected word lines” indicates a word line or word lines connected to a cell transistor of a memory cell MC not to be programmed, erased, or read from among the word lines WL1 to WLm. Likewise, the term “selected bit line” or “selected bit lines” indicates a bit line or bit lines connected to a cell transistor of a memory cell MC to be programmed, erased, or read from among the bit lines BL1 to BLn. The term “unselected bit line” or “unselected bit lines” indicates a bit line or bit lines connected to a cell transistor of a memory cell MC not to be programmed, erased, or read from among the bit lines BL1 to BLn.

The data input/output circuit 130 is connected to the memory cell array 110 via the bit lines BL1 to BLn. The data input/output circuit 130 operates under the control of the control logic 140. The data input/output circuit 130 selects a bit line in response to a bit line selection signal (not shown) from the address decoder 120. The data input/output circuit 130 receives power (e.g., voltage and/or current) from the control logic 140 and provides the power to a selected bit line.

The control logic 140 is configured to control overall operation of the resistive memory device 100. The control logic 140 is supplied with external power PWR and a control signal CTRL. The control logic 140 may generate power needed for internal operations using the external power PWR, where the internal operations include at least one of read, write, and erase operations. The control logic 140 controls the internal operations in response to the control signal CTRL.

In the depicted embodiment, the control logic 140 includes the power source 145 for generating power to be provided to selected bit lines (as well as unselected word lines). The control logic 140 provides power (e.g., voltage and/or current) generated by the selected bit line power source 145 to the address decoder 120 and/or the data input/output circuit 130.

Accordingly, the resistive memory device 100 according to embodiments of the inventive concept is configured to provide power generated by the selected bit line power source 145 to selected bit lines and unselected word lines. This reduces leakage current flowing to unselected memory cells by removing or decreasing the voltage difference between a selected bit line and an unselected word line.

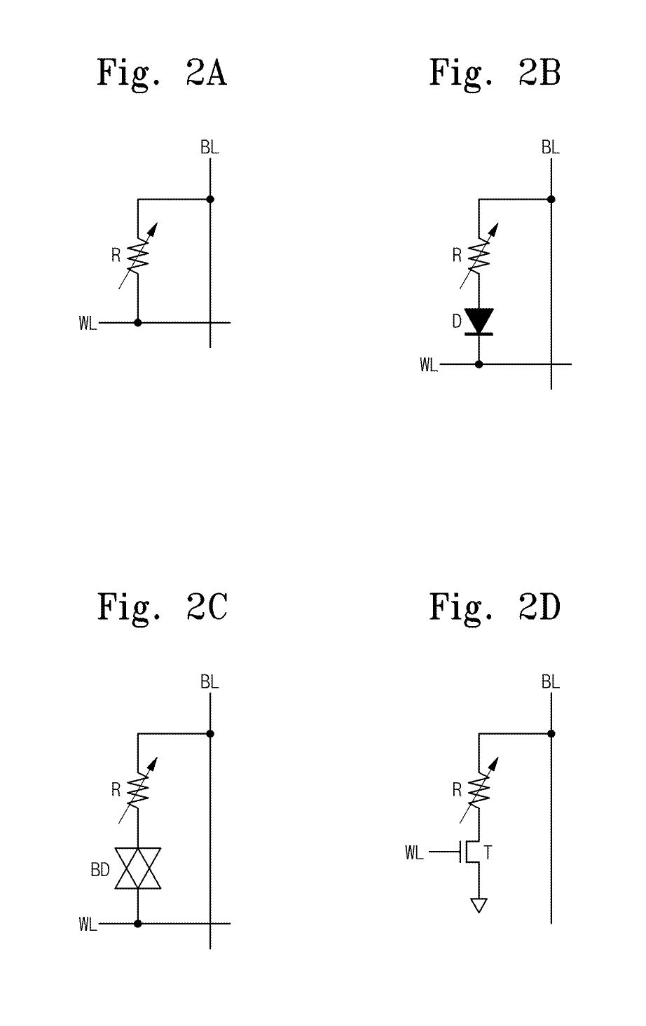

FIGS. 2A to 2D are circuit diagrams schematically illustrating a memory cell structure of a resistive memory device in FIG. 1, according to embodiments of the inventive concept. In particular, FIG. 2A depicts a resistive memory cell not including a selection element, and FIGS. 2B to 2D each depict a resistive memory cell including a selection element. Notably, the structure of the resistive memory cell is not limited to the illustrative configurations in FIGS. 2A to 2D.

Referring to FIG. 2A, the resistive memory cell includes a variable resistance element R connected to a bit line BL and a word line WL. Writing data in the resistive memory cell not including a selection element may be performed by applying a voltage between the bit line BL and the word line WL.

Referring to FIG. 2B, the resistive memory cell includes a variable resistance element R and a diode D. The variable resistance element R includes a variable resistance material for storing data. The diode D is a selection element (or, a switching element) that selectively supplies current to the variable resistance element R according to a bias condition of the word line WL and the bit line BL. The diode D is connected between the variable resistance element R and the word line WL, and the variable resistance element R is connected between the bit line BL and the diode D. Positions of the diode D and the variable resistance element R can be exchanged. The diode D may be turned on or off according to voltage of the word line WL. Thus, the resistive memory cell may not be driven when a specific voltage is provided to the word line (or, an unselected word line) WL.

Referring to FIG. 2C, the resistive memory cell includes a variable resistance element R and a bi-directional diode BD. The variable resistance element R includes a variable resistance material for storing data. The bi-directional diode BD is connected between the variable resistance element R and the word line WL, and the variable resistance element R is connected between the bit line BL and the bi-directional diode BD. Positions of the bi-directional diode BD and the variable resistance element R can be exchanged. The bi- directional diode BD may block a leakage current flowing to an unselected resistive memory cell.

Referring to FIG. 2D, the resistive memory cell includes a variable resistance element R and a transistor T. The transistor T is a selection element (or, a switching element) that selectively supplies current to the variable resistance element R according to voltage of the word line WL. The transistor T is connected between the variable resistance element R and the word line WL, and the variable resistance element R is connected between the bit line BL and the transistor T. Positions of the transistor T and the variable resistance element R can be exchanged. The resistive memory cell may be selected or unselected according to whether the transistor T is turned on or off according to voltage of the word line WL.

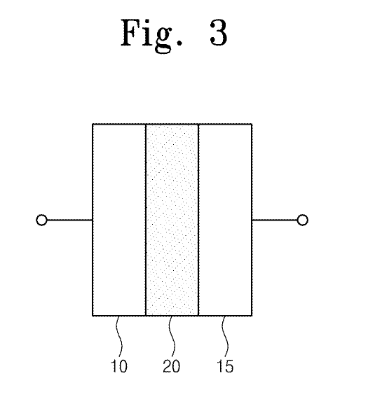

FIG. 3 is a diagram schematically illustrating a variable resistance element structure of a resistive memory cell in FIGS. 2A to 2D, according to an embodiment of the inventive concept. Referring to FIG. 3, the resistive memory cell includes a pair of electrodes 10 and 15 and a data storing film 20 interposed between the electrodes 10 and 15.

The electrodes 10 and 15 may be formed of metal, metallic oxide, or metallic nitride. For example, the electrodes 10 and 15 may be formed of Al, Cu, TiN, TixAlyNz, Ir, Pt, Ag, Au, polycrystalline silicon, W, Ti, Ta, TaN, WN, Ni, Co, Cr, Sb, Fe, Mo, Pd, Sn, Zr, Zn, IrO₂, StZrO₃, or the like.

The data storing film 20 may be formed of a bipolar resistance memory substance or a unipolar resistance memory substance. The bipolar resistance memory substance may be programmed to a set state or a reset state according to polarity of a pulse. The unipolar resistance memory substance may be programmed to a set state or a reset state by a pulse having the same polarity. The unipolar resistance memory substrate may include transient metal oxide, such as NiOₓ or TiOₓ, and the bipolar resistance memory substance may include materials in the Perovskite family, for example.

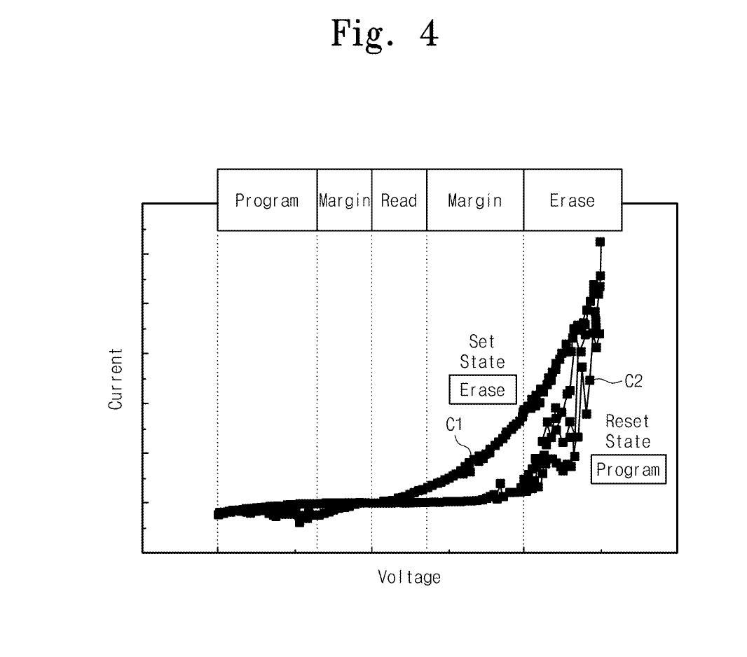

FIG. 4 is a graph illustrating hysteresis curves of a resistive memory cell in FIG. 2A, according to an embodiment of the inventive concept. In FIG. 4, the horizontal axis indicates voltage and the vertical axis indicates current. At the top of FIG. 4, the condition that the memory cell MC transitions between a set state (or, an erase state) and a reset state (or, a program state) is illustrated using voltage periods.

A first curve C1 is a voltage-current curve of memory cells having a set state (or, an erase state). A second curve C2 is a voltage-current curve of memory cells having a reset state (or, a program state). When the same voltage (e.g., a voltage having a level belonging to the read period) is applied to the memory cells MC, the amount of current flowing via a memory cell MC having a set state (or, an erase state) may be more than the amount of current flowing via a memory cell having a reset state (e.g., a program state). That is, a memory cell MC in a reset state (or, a program state) may have a larger resistance value than a memory cell in a set state (or, an erase state).

When a voltage corresponding to an erase period is applied to memory cells having a reset state (or, a program state), states of the memory cells may be changed into a set state (or, an erase state). Alternatively, when a current corresponding to a voltage of an erase period is applied to memory cells having a reset state (or, a program state), states of the memory cells may be changed into a set state (or, an erase state). If a voltage corresponding to a program period is applied to memory cells having a set state (or, an erase state), states of the memory cells may be changed into a reset state (or, a program state). Alternatively, in case that a current corresponding to a voltage of a program period is applied to memory cells having a set state (or, an erase state), states of the memory cells may be changed into a reset state (or, a program state).

In illustrative embodiments, a voltage bias at programming may be opposite to a voltage bias at erasing. At programming, a word line voltage may be lower than a bit line voltage. At erasing, a word line voltage may be higher than a bit line voltage Likewise, a current bias at programming may be opposite to a current bias at erasing. At programming, a current may flow to a word line from a bit line via a memory cell. At erasing, a current may flow to a bit line from a word line via a memory cell.

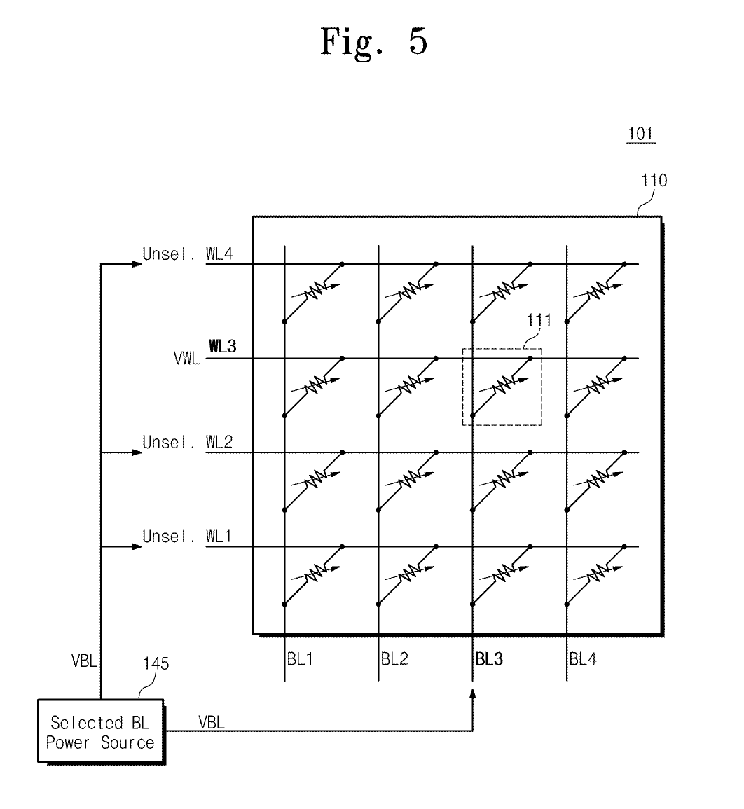

FIG. 5 is a diagram illustrating an operating method of a resistive memory device, according to an embodiment of the inventive concept. In particular, FIG. 5 shows a bias state when writing or reading of a resistive memory device 101 is performed by memory cell unit. The resistive memory device 101 includes a memory cell array 110. For ease of description, it is assumed that the memory cell array 110 includes four word lines WL1 to WL4 and four bit lines BL1 to BL4.

Referring to FIG. 5, an example is shown in which a memory cell 111 within a dotted-line box is a selected memory cell, a third word line WL3 connected to the memory cell 111 is a selected word line, and a third bit line BL3 connected to the memory cell 111 is a selected bit line. The remaining word lines WL1, WL2, and WL4 are unselected word lines, the remaining bit lines BL1, BL2, and BL4 are unselected bit lines, and the remaining memory cells are unselected memory cells.

As illustrated in FIG. 5, word line voltage VWL is provided to the selected word line WL3, and bit line voltage VBL is provided to the selected bit line BL3. When the word line voltage VWL has a higher level than the bit line voltage VBL, current may flow to the third bit line BL3 via the third word line WL3 and the memory cell 111. When the bit line voltage VBL has a higher level than the word line voltage VWL, current may flow to the third word line WL3 via the third bit line BL3 and the memory cell 111. The selected memory cell 111 may be programmed or read according to the bit line voltage VBL and the word line voltage VWL.

The selected bit line power source 145 is configured to supply the bit line voltage VBL to the unselected word lines WL1, WL2, and WL4, as well as to the selected bit line BL3. Providing the bit line voltage VBL to the unselected word lines WL1, WL2, and WL4 decreases the voltage difference between an unselected word line and a selected bit line. As the voltage difference between an unselected word line and a selected bit line decreases, leakage current flowing via an unselected memory cell is reduced. With the bias state of the resistive memory device 101 shown in FIG. 5, at reading or programming, no voltage difference is generated between an unselected word line and a selected bit line, and thus no current may be leaked via an unselected memory cell.

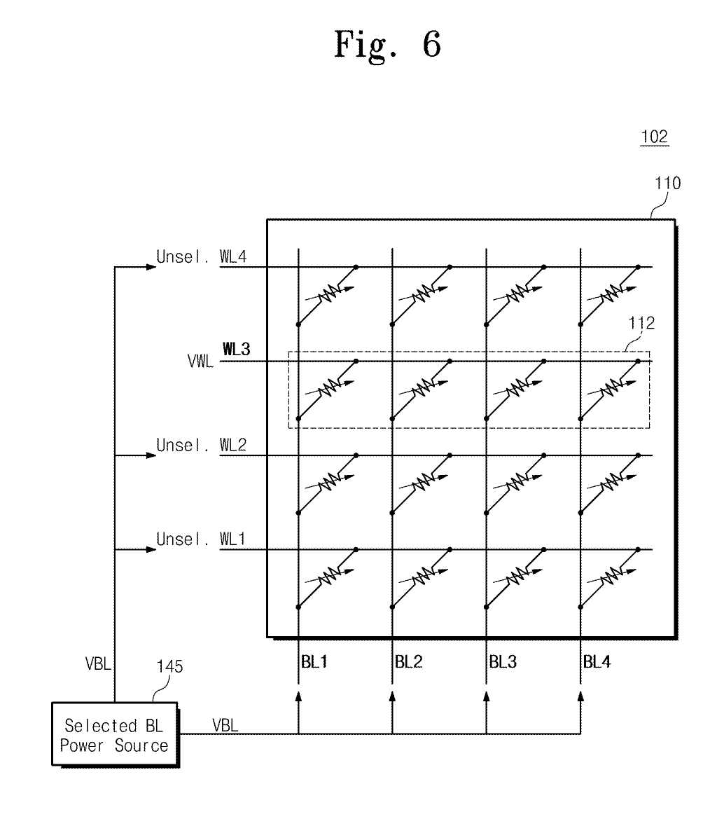

FIG. 6 is a diagram illustrating an operating method of a resistive memory device, according to another embodiment of the inventive concept. In particular, FIG. 6 shows a bias state when writing or reading of a resistive memory device 102 is performed by page unit. A page is a set of memory cells of the memory cell array 110 that are programmed or read at once during a program or read operation.

In FIG. 6, a dotted-line box indicates a selected page 112, which includes multiple memory cells. First to fourth bit lines BL1 to BL4 are selected bit lines. Also, a third word line WL3 is a selected word line, for example, and the remaining word lines WL1, WL2, and WL4 are be unselected word lines. As illustrated in FIG. 6, word line voltage VWL is provided to the selected word line WL3.

The selected bit line power source 145 is configured to provide bit line voltage VBL to the unselected word lines WL1, WL2, and WL4, as well as to the selected bit lines BL1 to BL4. With the bias state of the resistive memory device 102 shown in FIG. 6, at reading or programming, no voltage difference is generated between unselected word lines WL1, WL2, and WL4 and selected bit lines BL1 to BL4. Thus, no current may be leaked via an unselected memory cell.

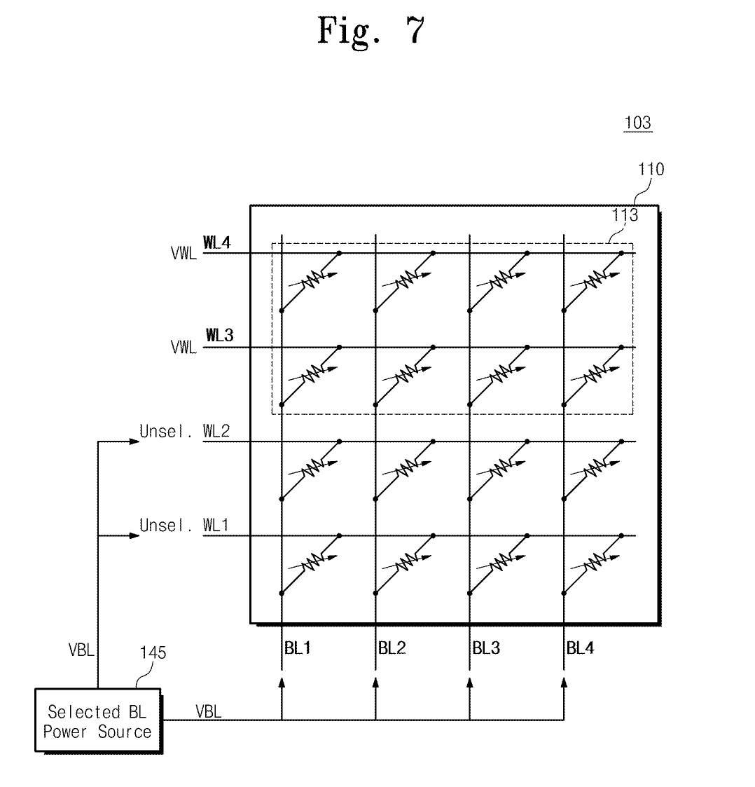

FIG. 7 is a diagram illustrating an operating method of a resistive memory device, according to still another embodiment of the inventive concept. In particular, FIG. 7 shows a bias state when erasing of a resistive memory device 103 is performed by sub-block unit. A sub-block is a set of memory cells of the memory cell array 110 that are erased at once to a specific state during an erase operation.

In FIG. 7, a dotted-line box indicates a selected sub-block 113, which includes multiple pages of multiple memory cells. First to fourth bit lines BL1 to BL4 are selected bit lines. Also, third and fourth word lines WL3 and WL4 are selected word lines, for example, and first and second word lines WL1 and WL2 are unselected word lines. The number of pages in the sub-block 113 is not limited to two. As illustrated in FIG. 7, word line voltage VWL is provided to the selected word lines WL3 and WL4.

The selected bit line power source 145 is configured to provide bit line voltage VBL to the unselected word lines WL1 and WL2, as well as to the selected bit lines BL1 to BL4. With the bias state of the resistive memory device 103 shown in FIG. 7, no voltage difference is generated between unselected word lines WL1 and WL2 and selected bit lines BL1 to BL4. Thus, no current may be leaked via an unselected memory cell.

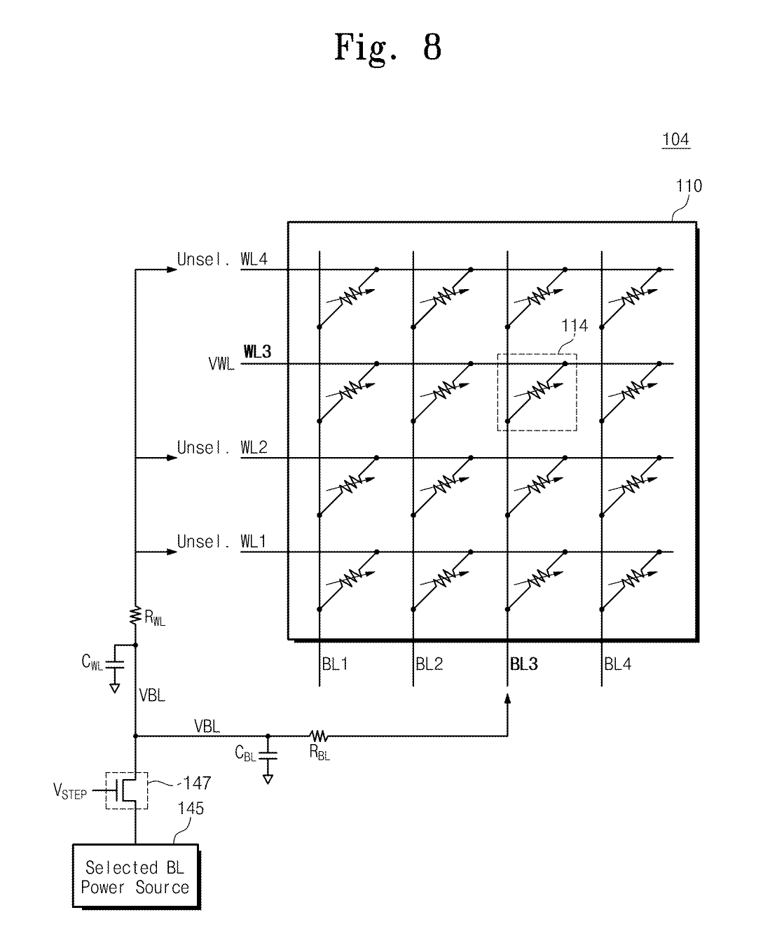

FIG. 8 is a diagram illustrating an operating method of a resistive memory device, according to still another embodiment of the inventive concept. In particular, FIG. 8 shows a bias state at a program or read operation of a resistive memory device 104. Referring to FIG. 8, a dotted-line box indicates a selected memory cell 114. The bias state shown in FIG. 8 may be the same as that described above with reference to FIG. 5. That is, word line voltage VWL is provided to a selected word line WL3, and bit line voltage VBL is provided to a selected bit line BL3 and unselected word lines WL1, WL2, and WL4.

As illustrated in FIG. 8, unselected word lines WL1, WL2, and WL4 may have word line parasitic resistance R_{WL} and parasitic capacitance C_{WL}. The selected bit line BL3 may have bit line parasitic resistance R_{BL} and parasitic capacitance C_{BL}. The word line parasitic resistance R_{WL} and the bit line parasitic resistance R_{BL} may have different values. For this reason, although the same bit line voltage VBL is output by the selected bit line power source 145, different voltages may be provided to the selected bit line BL3 and the unselected word lines WL1, WL2, and WL4.

To avoid this result, the resistive memory device 104 according to an embodiment of the inventive concept is configured to provide bit line voltage VBL, which is stepwise increased, to lessen influences due to parasitic resistance and capacitance. Therefore, resistive memory device 104 further includes a step voltage generator 147, which is connected to the output of the selected bit line power source 145, as illustrated in FIG. 8. The step voltage generator 147 may be implemented using various elements. For example, FIG. 8 illustrates the step voltage generator 147 being implemented as a transistor. Step voltage V_{STEP} is applied to a gate of the transistor, which generates the bit line voltage VBL stepwise increased in response to the step voltage V_{STEP}.

The resistive memory device 104 in FIG. 8 reduces leakage current generated due to parasitic resistance or capacitance difference between a word line and a bit line. The discussion of the resistive memory device 104 in FIG. 8 is applicable to program and read operations being executed by memory cell unit or page unit and to erase operations being executed by sub-block unit, for example.

A resistive memory device according to an embodiment of the inventive concept may be incorporated in various products. For example, the resistive memory device may be applied to storage devices, such as a memory card, an USB memory, a solid state drive (SSD), and the like, as well as to electronic devices, such as a personal computer, a digital camera, a camcorder, a cellular phone, an MP3 player, a PMP, a PSP, a PDA, and the like.

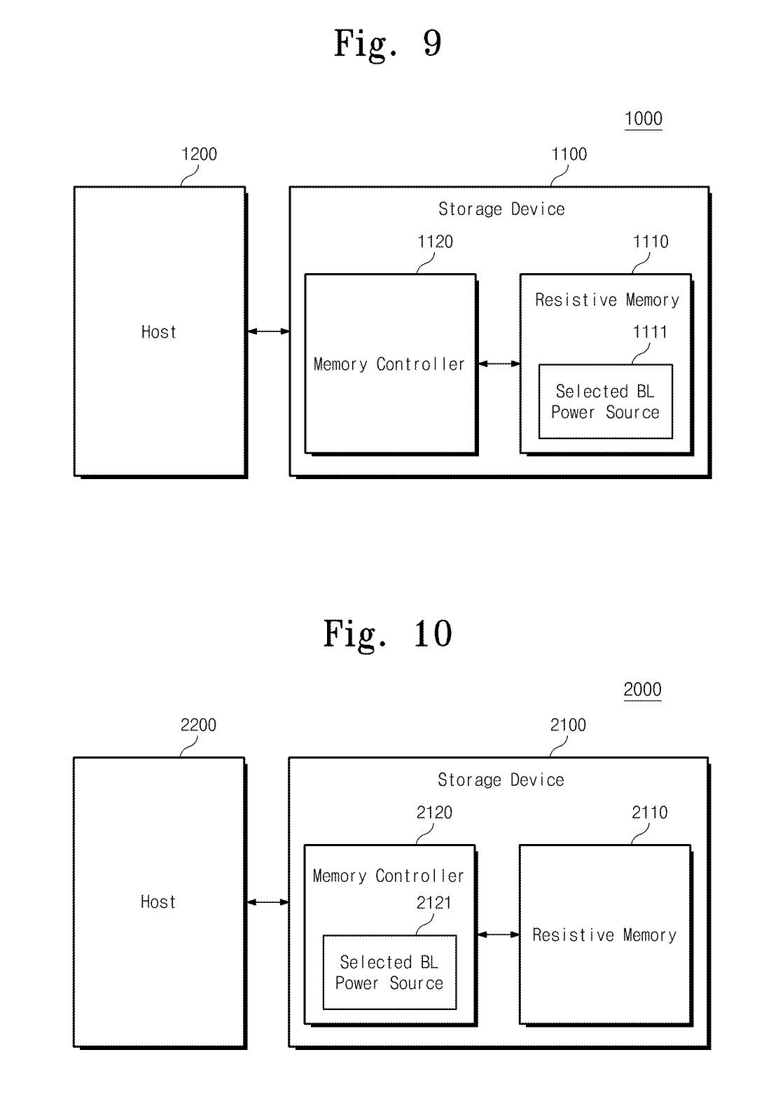

FIGS. 9 and 10 are block diagrams schematically illustrating various applications of a resistive memory device, according to embodiments of the inventive concept. Referring to FIGS. 9 and 10, memory systems 1000 and 2000 include storage devices 1100 and 2100 connected to hosts 1200 and 2200, respectively. The storage devices 1100 and 2100 include a resistive memories 1110 and 2110 and memory controllers 1120 and 2120. Each of the storage devices 1100 and 2100 include a storage medium, such as a memory card (e.g., SD, MMC, etc.) or an attachable handheld storage device (e.g., USB memory, etc.). The storage devices 1100 and 2100 may transmit and receive data to and from the hosts 1200 and 2200 via corresponding host interfaces. The storage devices 1100 and 2100 may be powered by the hosts 1200 and 2200 to execute internal operations.

The storage device 1100 in FIG. 9 includes a selected bit line power source 1111 within the resistive memory 1110. The resistive memory 1110 is configured to provide a selected bit line and unselected word lines with bit line voltage VBL, is generated internally. The storage device 2100 in FIG. 10 includes a selected bit line power source 2121 within the memory controller 2120. Although not shown in FIG. 10, the memory controller 2120 may further include a step voltage generator 147 described in FIG. 8. The resistive memory 2110 provides a selected bit line and unselected word lines with bit line voltage VBL, which is provided by an external device (e.g., the memory controller 2120).

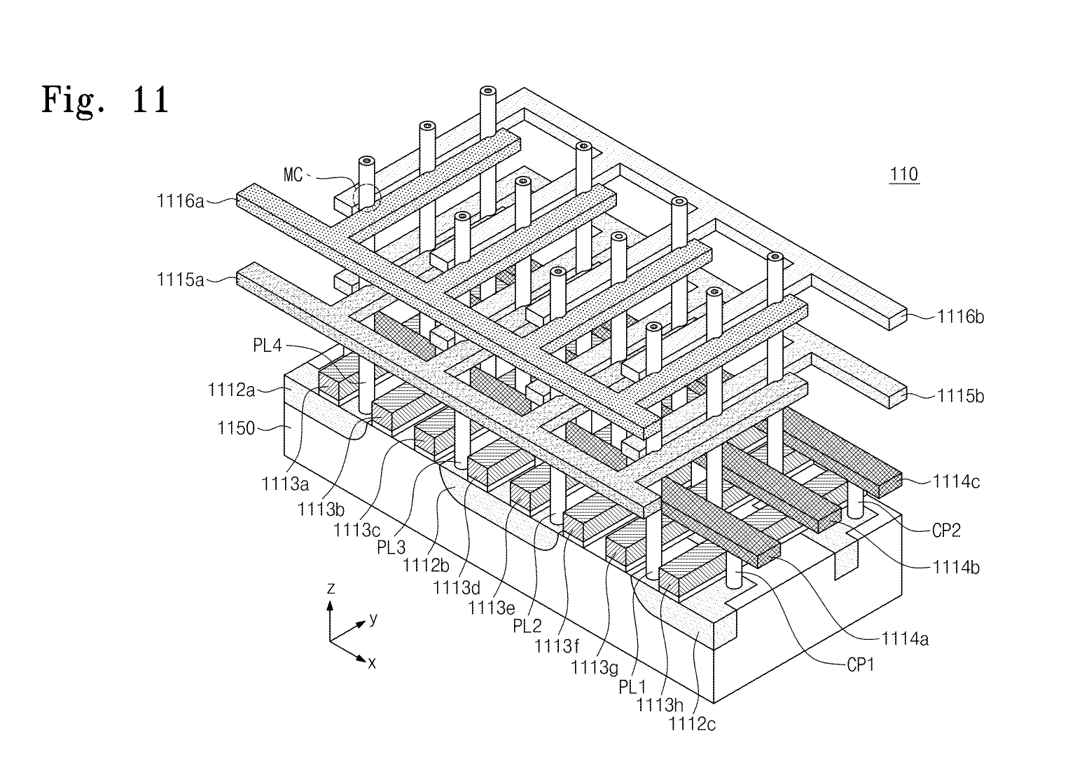

A resistive memory device, according to embodiments of the inventive concept, may include a memory cell array having a three-dimensional structure. For example, FIG. 11 is a perspective view schematically illustrating a three-dimensional structure of a memory cell array in FIG. 1. Referring to FIG. 11, a memory cell array 110 include structures extending along multiple directions x, y, and z.

The memory cell array 110 is formed on a substrate 1150. For example, the substrate 1150 may be formed of a p-well, in which an element such as boron is injected. Alternatively, the substrate 1150 may be a pocket p-well provided within an n-well. For purpose of discussion, it is assumed that the substrate 1150 is a p-well, although the substrate 1150 is not limited thereto.

In the depicted embodiment, multiple doping regions, indicated by illustrative doping regions 1112a to 1112c, are formed in the substrate 1150. For example, the doping regions 1112a to 1112c may be formed of an n-type conductor different from the substrate 1150. However, the inventive concept is not limited thereto. The doping regions 1112a to 1112c may be formed sequentially in the x-axis direction. This structure may be iterated in the y-axis direction. Word lines 1113a to 1113h connected to metal lines formed at multiple layers may be formed over the doping regions 1112a to 1112c and are electrically isolated from the doping regions 1112a to 1112c.

The doping regions 1112a to 1112c may be connected to multiple bit lines 1114a to 1114c extending in the x-axis direction by contact plugs, indicated by illustrative contact plugs CP1 and CP2. In addition, the doping regions 1112a to 1112c may be connected to vertical electrodes of multiple pillars, indicated by illustrative pillars PL1 to PL4. That is, the bit lines 1114a to 1114c may be connected to vertical electrodes of the pillars PL1 to PL4 through the doping regions 1112a to 1112c. Each of the pillars PL1 to PL4 may be connected with metal lines 1115a, 1115b, 1116a, and 1116b stacked at multiple layers. The metal lines 1115a and 1115b, for example, connected to pillars PL1 to PL4 at multiple metal layers in a comb shape, may be connected to a global word line, respectively.

According to the above description, the memory cell array 110 of the resistive memory device may be formed to have a three-dimensional structure. As discussed above with regard to FIG. 1, the selected bit line power source 145 supplies power to selected bit lines and unselected word lines of the memory cell array 110 having the three-dimensional structure, thereby reducing leakage current by decreasing the voltage difference between unselected word lines and a selected bit line. However, the inventive concept is not limited thereto. Resistive memory cells can be stacked in various manners.

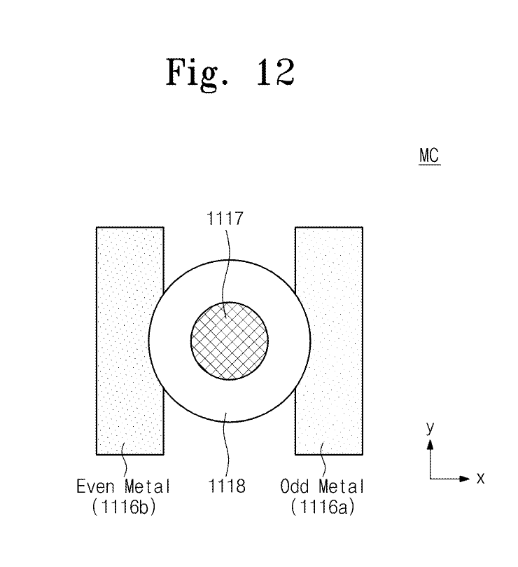

FIG. 12 is a cross-sectional view of a resistive memory cell formed at one layer in FIG. 11, according to an embodiment. Referring to FIG. 12, a memory cell MC may include a pillar located between first (odd) metal line 1116a and second (even) metal line 1116b.

A pillar penetrating in a direction (e.g., z-axis direction) perpendicular to a substrate may be formed between the first and second metal lines 1116a and 1116b forming a horizontal electrode. The pillar may include a data storing film 1117 and a vertical electrode 1118 that are formed in a cylindrical shape. A variable resistance memory cell is formed by the vertical electrode 1118 connected to a bit line and the first and second metal lines 1116a and 1116b connected to a word line. The data storing film 1117 may be formed by etch and deposition processes, for example, in a vertical direction. The vertical electrode 1118 may be formed by a deposition process, for example, such as physical vapor deposition (PVD), chemical vapor deposition (CVD), or atomic layer deposition (AVD).

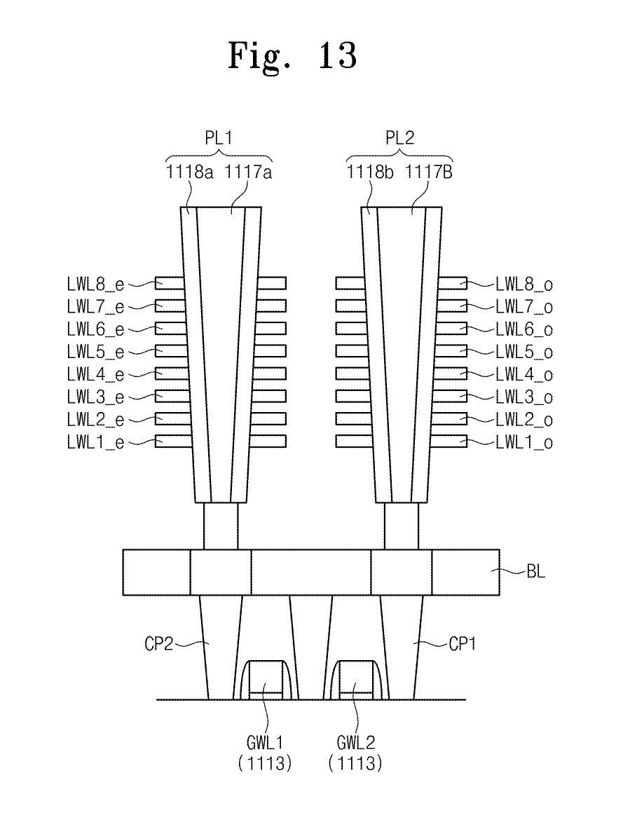

FIG. 13 is a cross-sectional view of a memory cell array in FIG. 11, according to an embodiment. Referring to FIG. 13, the memory cell array includes pillars PL1 and PL2, where pillar PL1 forms vertical electrode 1118a and data storing film 117a and pillar PL2 forms vertical electrode 1118b and data storing film 117b to provide variable resistance memory cells. The memory cell array further includes multiple horizontal electrodes LWL1_e to LWL8_e and LWL1_o to LWL8_o stacked in a direction perpendicular to a substrate and connected to the vertical electrodes 1118a and 1118b, respectively, and bit lines connected to the vertical electrodes 1118a and 1118b via doping regions. Global word lines 1113 (GWL1 and GWL2) provide word line voltages to the multiple horizontal electrodes horizontal electrodes LWL1_e to LWL8_e and LWL1_o to LWL8_o.

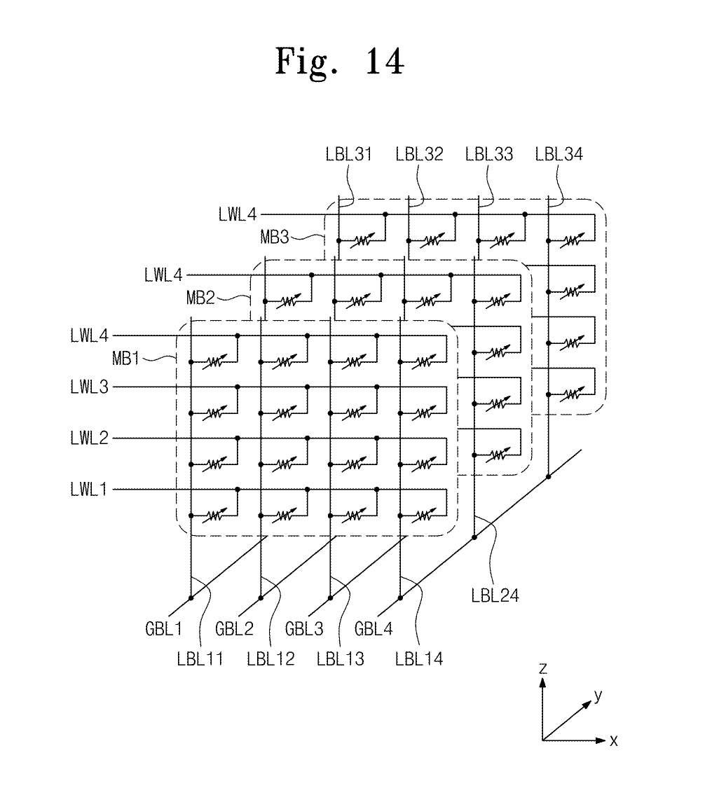

FIG. 14 is a circuit diagram schematically illustrating a memory cell array in FIG. 11, according to an embodiment. Referring to FIG. 14, memory cell array 110 includes multiple memory blocks MB1 to MB3, each of which forms a memory block unit in an x-z plane.

The memory cell array 110 in the depicted embodiment includes multiple local bit lines LBL11 to LBL43 extending in parallel in a z-axis direction and multiple local word lines LWL1 to LWL4 extending in parallel in a y-axis direction perpendicular to the z-axis direction. Although not shown, each of the memory blocks MB1 to MB3 may be connected to different local word lines LWL.

Local bit lines LBL11 to LBL43 formed by vertical channels of pillars are connected to global bit lines GBL1 to GBL4, respectively. Variable resistive memory cells of the memory cell array 110 are be connected to the local word lines LWL1 to LWL4 and the local bit lines LBL11 to LBL43 in each of the memory blocks MB1 to MB 3. For example, variable resistive memory cells in the memory block MB1 are connected to corresponding local word lines LWL1 to LWL4 and the local bit lines LBL11 to LBL14; variable resistive memory cells in the memory block MB2 are connected to corresponding local word lines LWL1 to LWL4 and the local bit lines LBL21 to LBL24; and variable resistive memory cells in the memory block MB3 are connected to corresponding local word lines LWL1 to LWL4 and the local bit lines LBL31 to LBL34. The variable resistive memory cells may be programmed or sensed using voltages applied to the local word lines LWL1 to LWL4 and/or the local bit lines LBL11 to LBL43.

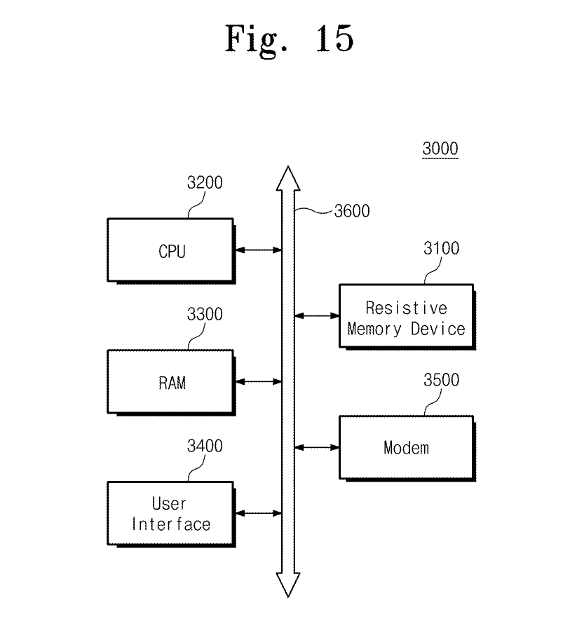

FIG. 15 is a block diagram schematically illustrating a computing system including a resistive memory device, according to an embodiment of the inventive concept. Referring to FIG. 15, a computing system 3000 includes a resistive memory device 3100, a central processing unit (CPU) 3200, random access memory (RAM) 3300, a user interface 3400, and a modem 3500, such as a baseband chipset, which are electrically connected to a system bus 3600.

The resistive memory device 3100 is configured to provide the same bit line voltage VBL to selected bit line(s) and unselected word line(s), as described above. Accordingly, leakage current flowing to an unselected memory cell is reduced or eliminated.

If the computing system 3000 is a mobile device, it may further include a battery (not shown), which powers the computing system 3000. Although not shown in FIG. 15, the computing system 3000 may further include an application chipset, a camera image processor (CIS), a mobile DRAM, and the like.

A resistive memory device according to an embodiment of the inventive concept may be used as a storage class memory (SCM), which may be a generic term for a memory that provides both nonvolatile characteristics and random-access characteristics. The above described PRAM, FRAM, MRAM, and the like, as well as the resistive memory (RRAM) may be used as the storage class memory. For example, the storage class memory may be used as a data storage memory instead of flash memory Likewise, the storage class memory may be used as a main memory instead of synchronous DRAM. Further, one storage class memory may be used in place of flash memory and synchronous DRAM.

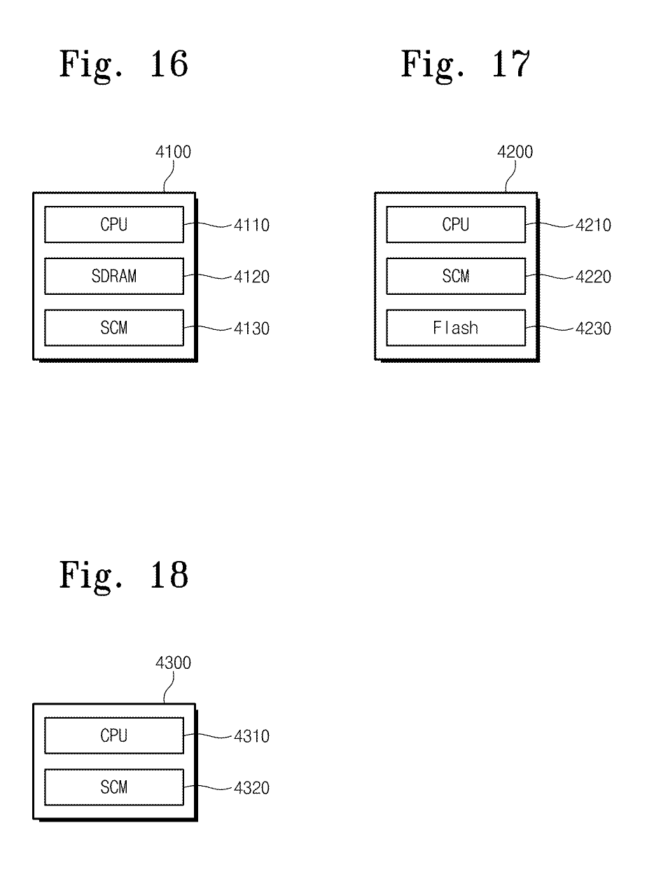

FIG. 16 is a block diagram schematically illustrating a memory system in which flash memory is replaced with storage class memory using resistive memory, according to an embodiment of the inventive concept. Referring to FIG. 16, a memory system 4100 includes a CPU 4110, synchronous DRAM (SDRAM) 4120, and storage class memory (SCM) 4130. The SCM 4130 may be a resistive memory used as a data storage memory instead of flash memory.

The SCM 4130 may access data at higher speeds as compared to flash memory. For example, in a personal computer (PC), the CPU 4110 may operate by a frequency of about 4 GHz, and the resistive memory SCM 4130 may provide access speeds higher than flash memory. Thus, the memory system 4100 including the SCM 4130 may provide relatively higher access speeds than a memory system including flash memory.

FIG. 17 is a block diagram schematically illustrating a memory system in which synchronous DRAM is replaced with storage class memory using resistive memory according to an embodiment of the inventive concept. Referring to FIG. 17, a memory system 4200 includes a CPU 4210, SCM 4220, and flash memory 4230. The SCM 4220 may be used as main memory instead of SDRAM.

Power consumed by the SCM 4220 may be less than that consumed by the SDRAM. Main memory may take about 40 percent of power consumed by a computing system. For this reason, reducing power consumption of the main memory has been developed. Compared with the DRAM, the SCM 4220 may reduce 53 percent of dynamic energy consumption on average and about 73 percent of energy consumption due to power leakage. Thus, the memory system 4200 having the SCM 4220, according to an embodiment of the inventive concept, may reduce power consumption compared with a memory system including an SDRAM.

FIG. 18 is a block diagram schematically illustrating a memory system in which synchronous DRAM and flash memory are replaced with storage class memory using resistive memory according to an embodiment of the inventive concept. Referring to FIG. 18, a memory system 4300 includes CPU 4310 and SCM 4320. Herein, the SCM 4320 may be used as main memory instead of SDRAM and as data storage memory instead of flash memory. The memory system 4300 may be advantageous in terms of data access speed, low power, cost, and use of space.

A resistive memory device according to embodiments of the inventive concept may be packed according to various types of packages, such as PoP (Package on Package), Ball grid arrays (BGAs), Chip scale packages (CSPs), Plastic Leaded Chip Carrier (PLCC), Plastic Dual In-Line Package (PDI2P), Die in Waffle Pack, Die in Wafer Form, Chip On Board (COB), Ceramic Dual In-Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), System In Package (SIP), Multi Chip Package (MCP), Wafer-level Fabricated Package (WFP), Wafer-Level Processed Stack Package (WSP), and the like.

While the inventive concept has been described with reference to exemplary embodiments, it will be apparent to those skilled in the art that various changes and modifications may be made without departing from the spirit and scope of the present inventive concept. Therefore, it should be understood that the above embodiments are not limiting, but illustrative.

What is claimed is:

1. A resistive memory device comprising:
a memory cell array comprising a plurality of memory cells connected to a plurality of word lines and a plurality of bit lines; and
control logic configured to provide a bit line voltage to at least one selected bit line of the plurality of bit lines and to provide the bit line voltage to unselected word lines of the plurality of word lines.

2. The resistive memory device of claim 1, wherein the control logic comprises a selected bit line power source configured to generate the bit line voltage.

3. The resistive memory device of claim 2, wherein the control logic is configured to perform a read operation or a write operation by memory cell unit.

4. The resistive memory device of claim 3, wherein the selected bit line power source is configured to provide the bit line voltage to one selected bit line and to the unselected word lines, other than one selected word line.

5. The resistive memory device of claim 2, wherein the control logic is configured to perform a read operation or a write operation by page unit.

6. The resistive memory device of claim 5, wherein the selected bit line power source is configured to provide the bit line voltage to a plurality of selected bit lines and to the unselected word lines, other than one selected word line.

7. The resistive memory device of claim 2, wherein the control logic is configured to perform an erase operation by a sub-block unit.

8. The resistive memory device of claim 7, wherein the selected bit line power source is configured to provide the bit line voltage to a plurality of selected bit lines and to the unselected word lines, other than a plurality of selected word lines.

9. The resistive memory device of claim 2, further comprising:
a step voltage generator configured to generate a stepwise increasing bit line voltage using power from the selected bit line power source.

10. The resistive memory device of claim 1, wherein each memory cell of the memory cell array comprises a variable resistance element connected to a word line of the plurality of word lines and a bit line of the plurality of bit lines.

11. The resistive memory device of claim 1, wherein the memory cell array comprises a three-dimensional structure.

12. A memory system comprising:
a resistive memory device configured to provide a bit line voltage to a selected one of a plurality of bit lines and to unselected word lines of a plurality of word lines; and
a memory controller configured to control the resistive memory device.

13. The memory system of claim 12, wherein the resistive memory device comprises a selected bit line power source configured to generate the bit line voltage to be supplied to the selected bit line and the unselected word lines.

14. The memory system of claim 13, wherein the resistive memory device further comprises a step voltage generator configured to generate a stepwise increasing bit line voltage using power from the selected bit line power source.

15. The memory system of claim 12, wherein the memory controller comprises a selected bit line power source configured to generate the bit line voltage to be supplied to the selected bit line and the unselected word lines.

16. The memory system of claim 15, wherein the memory controller further comprises a step voltage generator configured to generate a stepwise increasing bit line voltage using power from the selected bit line power source.

17. A resistive memory device comprising:
a memory cell array comprising a plurality of memory cells connected to a plurality of word lines and a plurality of bit lines;
an address decoder connected to the memory cell array via the plurality of word lines, and configured to select at least one word line of the plurality of word lines corresponding to at least one selected memory cell of the plurality of memory cells in response to an input address during an internal operation;
a data input/output circuit connected to the memory cell array via the plurality of bit lines, and configured to select at least one bit line of the plurality of bit lines corresponding to the at least one selected memory cell in response to a bit line selection signal from the address decoder during the internal operation; and
control logic configured to control the internal operation in response to a control signal, and to provide a bit line voltage to the at least one selected bit line and to unselected word lines of the plurality of word lines other than the at least one selected word line, thereby decreasing a voltage difference between the unselected word lines and the at least one selected bit line.

18. The resistive memory device of claim 17, wherein the control logic comprises a selected bit line power source configured to generate the bit line voltage.

19. The resistive memory device of claim 18, wherein the control logic further comprises a step voltage generator connected to an output of the selected bit line power source, and configured to provide a stepwise increase of the bit line voltage, compensating for at least one of parasitic resistance and parasitic capacitance of the unselected word lines or the at least one selected bit line.

20. The resistive memory device of claim 19, wherein the step voltage generator comprises a transistor, the transistor comprising a gate to which a step voltage is applied for controlling the stepwise increase of the bit line voltage.
